(19) United States
(12) Patent Application Publication
(10) Pub. No.: US 2013/0061900 A1
(43) Pub. Date: Mar. 14, 2013

(54) THERMOELECTRIC DEVICE

(71) Applicant: TAKAHISA TACHIBANA, Hamamatsu-shi (JP)

(72) Inventor: TAKAHISA TACHIBANA, Hamamatsu-shi (JP)

(73) Assignee: Yamaha Corporation, Hamamatsu-shi (JP)

(21) Appl. No.: 13/607,854

(22) Filed: Sep. 10, 2012

(30) Foreign Application Priority Data
Sep. 12, 2011 (JP) 2011-198398

(51) Int. Cl. H01L 35/30

(52) U.S. Cl. 136/203

(57) ABSTRACT

A thermoelectric device absorbs heat from an object coming into contact with a heat absorber, moves the heat absorbed via a thermoelectric module to a radiator, and radiates the heat from the radiator. The support member has a lower surface that is bonded to a radiator upper surface, and a side surface that is placed so as to face the side surface of the heat absorber. The support member forms a tilling region between the support member and the side surface, and a sealing member fills the filling region. The thermoelectric module is placed in an internal space 3 which is formed by the heat absorber, the radiator, the support member and the sealing member.

### BACKGROUND OF THE INVENTION

1. Field of the Invention

The present invention relates to a technique that suppresses deterioration of a thermoelectric module due to moisture in a thermoelectric device.

Priority is claimed on Japanese Patent Application No. 2011-198398, filed on Sep. 12, 2011, the contents of which are incorporated herein by reference.

2. Description of Related Art

There is a technique which places a thermoelectric module between a heat absorber and a radiator, moves heat from the heat absorber to the radiator by a Peltier effect, and regulates the temperature of the heat absorber. When condensation occurs in the thermoelectric module, this can lead to short circuiting, rusting, and deterioration. Japanese Patent No. 3252902 discloses a temperature control unit in which a Peltier module (a thermocouple module) is interposed between a case and an electrode tip holder, and a hermetic sealing resin fills a gap between the case and the electrode tip holder. Furthermore, Japanese Unexamined Patent Application, First Publication No. 2007-294864 discloses a technique which provides a seal material between upper and lower support substrates of the thermoelectric module so as to come into contact with both sides of the support substrate, and forms an enclosed space for sealing a thermoelectric element.

As in a temperature control unit according to Japanese Patent No. 3252902, in a case of blocking a region (a gap) interposed between two members (the case and the electrode tip holder) by a sealing member (resin) to prevent the moisture from entering, the greater the distance between both members in the region, the greater the width of a course in which the moisture enters is increased, and thus the moisture entering through the sealing member is increased. If the sizes of the thermoelectric module in a direction of the insertion are different depending on unevenness at the time of the production or the like, a distance between the members placed with the thermoelectric module interposed therebetween is changed. As a result, the width of the course is increased, and in some cases, the moisture easily enters.

In a thermoelectric module according to Japanese Unexamined Patent Application, First Publication No. 2007-294864, side surfaces of the upper and lower support substrates are exposed to the outside of the enclosed space. In the thermoelectric module, in a case where the temperature of one support substrate is lowered due to the movement of heat, condensation may occur on a portion of the support substrates exposed to the outside of the enclosed space. If an amount of water droplet attached due to the dew condensation is large, the upper and lower support substrates are connected to each other via the water droplet, and heat is moved. In that case, a temperature gradient between the support substrates is reduced, and performance as the thermoelectric module drops. Furthermore, if the size of the thermoelectric element is increased, and the distance between the upper and lower support substrates fluctuates, a gap is generated between the sealing member and the support substrates, and there was a concern that an effect of sealing the thermoelectric element is damaged.

The sealing member hinders the motion of the thermoelectric element, which can become a cause that destroys the thermoelectric element and a joining portion between the thermoelectric element and the support substrates.

### SUMMARY OF THE INVENTION

The present invention has been made under such circumstances, and an object thereof is to suppress fluctuation of a width of a gap (an entrance path of moisture) blocked by a sealing member in an enclosed space which is formed by two support substrates with a thermoelectric module interposed therebetween and a sealing member.

In order to solve the problem mentioned above, according to the present invention, there is provided a thermoelectric device which includes: a thermoelectric module having an upper surface serving as one of a heat absorption surface or a radiation surface, a lower surface serving as the other of the heat adsorption surface or the radiation surface, and a side portion intersecting an outer circumference of the upper surface and an outer circumference of the lower surface; a first thermal conductor which has a first surface and a side surface intersecting the first surface and in which the first surface comes into close contact with the upper surface of the thermoelectric module so that the outer circumference of the upper surface is located inside the outer circumference of the first surface to exchange heat with the thermoelectric module through the first surface; a second thermal conductor which has a second surface that is greater than the first surface and in which the second surface comes into close contact with the lower surface of the thermoelectric module so that the outer circumference of the lower surface is located inside the outer circumference of the second surface to exchange heat with the thermoelectric module through the second surface; a support member which is fixed to the second surface so as to surround the periphery of the side surface of the first thermal conductor and the side portion of the thermoelectric module at intervals with the side surface and the side portion; and a sealing member which fills between the side surface of the first thermal conductor and the support member, wherein the thermoelectric module is placed in an internal space which is formed by the first thermal conductor, the second thermal conductor, the support member and the sealing member and isolated from the external space.

In a preferred aspect, the sealing member is separated from the second thermal conductor.

In another preferred aspect, the thermoelectric device of the present invention includes a bent groove which is formed on a surface facing the second surface of the support member to cause the external space and the internal space to communicate with each other, and a lead wire which is provided inside the groove and has one end electrically connected to the thermoelectric module and the other end placed in the external space.

In still another preferred aspect, a width of at least a part of a width of the groove in a sectional direction is narrower than a thickness of the lead wire.

Still another preferred aspect has a relay wire which has a cross-sectional area that is smaller than the thickness of the lead wire and electrically connects one end of the lead wire with the thermoelectric module.

According to the present invention, in a case where the sizes in a hight or thickness direction of the thermoelectric module interposed by two members (the support substrates) are different, it is possible to suppress fluctuation of the width of the gap (hereinafter, referred to as a “filling region”) filled with the sealing member.

### BRIEF DESCRIPTION OF THE DRAWINGS

FIG. 1 is a plan view that shows a thermoelectric device according to an embodiment of the present invention.

FIG. 2 is a cross-sectional view taken along a line II-II shown in FIG. 1.

FIG. 3 is a cross-sectional view taken along a line shown in FIG. 2.

FIG. 4 is a plan view that shows a groove in an embodiment of the present invention.

FIGS. 5A and 5B are a side view and a plan view that show a relay wire in an embodiment of the present invention.

FIGS. 6A to 6C are cross-sectional views that show a filling region in an embodiment of the present invention.

FIGS. 7A and 7B are a side view and a plan view that show a relay wire in Modified Example 1 of the present invention.

FIG. 8 is a cross-sectional view that shows a thermoelectric device according to Modified Example 2 of the present invention.

FIG. 9 is a cross-sectional view that shows a thermoelectric device according to Modified Example 3 of the present invention.

FIG. 10 is a cross-sectional view that shows a thermoelectric device according to Modified Example 4 of the present invention.

FIG. 11 is a cross-sectional view that shows a filling region in the Modified Example 4 of the present invention.

FIG. 12 is a plan view that shows a groove in Modified Example 5 of the present invention.

FIG. 13 is a plan view that shows an accumulation portion in Modified Example 16 of the present invention.

FIG. 14 is a cross-sectional view that shows a thermoelectric device according to Modified Example 17 of the present invention.

FIG. 15 is a cross-sectional view that shows a thermoelectric device according to Modified Example 18 of the present invention.

FIG. 16 is a cross-sectional view that shows a thermoelectric device according to Modified Example 19 of the present invention.

### DESCRIPTION OF PREFERRED EMBODIMENTS

### Embodiment

Hereinafter, an embodiment of the present invention will be described with reference to the drawings.

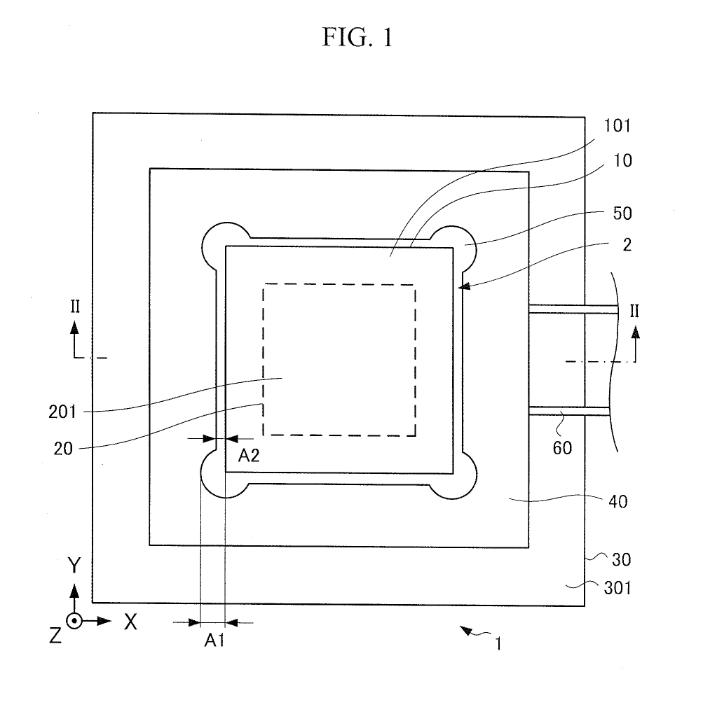

FIG. 1 is an outline view of a thermoelectric device 1 according to the embodiment. In the following drawings including FIG. 1, directions are indicated by three orthogonal axes X, Y and Z. In FIG. 1, a thermoelectric device 1 viewed from a negative direction of the Z axis is indicated. The thermoelectric device 1 includes a heat absorber 10, a thermoelectric module 20, a radiator 30, a support member 40, a sealing member 50, and two lead wires 60. In FIG. 1, the thermoelectric module 20 covered in the heat absorber 10 is indicated by a broken line.

The heat absorber 10 is a thermal conductor that is made of a copper, aluminum or the like and is formed in a rectangular parallelepiped shape. In FIG. 1, an upper surface 101 which is one of six surfaces of the heat absorber 10 is visible. The upper surface 101 is a square surface. The heat absorber 10 is placed so that two sides perpendicular to each other of the upper surface 101 go along the X axial direction and the Y axial direction. The thermoelectric module 20 is placed on a lower surface 102 of the heat absorber 10.

The thermoelectric module 20 has a plurality of thermoelectric elements, an electrode which electrically connects the thermoelectric elements, and two plate-like insulators which interpose the thermoelectric elements and the electrode, and these are formed so as to be substantially a rectangular parallelepiped shape. The thermoelectric module 20 is placed so that the upper surface 201 serving as the heat absorption surface faces the lower surface 102 of the heat absorber 10. The upper surface 201 is a square-shaped surface having an area that is smaller than the upper surface 101 and the lower surface 102 of the heat absorber 10. The thermoelectric module 20 is placed so that two sides perpendicular to each other of the upper surface 201 follow the X axis direction and the Y axis direction. Furthermore, the thermoelectric module 20 is placed so that the center of the upper surface 201 coincides with the centers of the surfaces 101 and 102 of the heat absorber 10.

The radiator 30 is a thermal conductor that is made of a copper, aluminum or the like and is formed in a rectangular parallelepiped shape. The radiator 30 is placed so that an upper surface 301 which is one of six surfaces faces the lower surface 202 of the heat absorber 10. The upper surface 301 is a square-shaped surface having an area that is greater than the upper surface 101 and the lower surface 102 of the heat absorber 10. The radiator 30 is placed so that two sides perpendicular to each other the upper surface 301 follow the X axis direction and the Y axis direction. Furthermore, the radiator 30 is placed so that the center of the upper surface 301 coincides with the centers of the surfaces 101 and 102.

The support member 40 is made of a plastic or a ceramic and is formed in a shape which surrounds the periphery of the heat absorber 10 and the thermoelectric module 20 when viewed from the Z axis direction of FIG. 1. The periphery mentioned here does not include the upper surface 101 side of the heat absorber 10, and in FIG. 1, the upper surface 101 is exposed to outside without being covered by the support member 40. A filling region 2 is formed between the support member 40 and the heat absorber 10. The filling region 2 has a circular shape of a radius A1 around each corner in portions of corners of the heat absorber 10 and has a groove shape of a width A2 that is shorter than the radius A1 in portions other than the portions of the corners. The width of the filling region 2 refers to a distance (interval) between the heat absorber 10 and the support member 40 in a portion forming the filling region 2, and the longer the distance, the wider the width of the filling region 2. The support member 40 is configured so that the portions of the corners have the circular shape and the width of the filling region 2 formed between the support member 40 and the heat absorber 10 is wider than other portions. As a result, when the heat absorber 10 or the support member 40 is assembled, the portions of the corners of the heat absorber 10 are prevented from coming into contact with the support member 40 due to the error.

The sealing member 50 fills the filling region 2. The sealing member 50 is a synthetic resin such as epoxy resin, acrylic resin, silicone resin or the like and has moisture permeability that is higher than the support member 40.

Two lead wires 60 are lead wires that are connected to the thermoelectric module 20 and supply the electric power to the thermoelectric module 20.

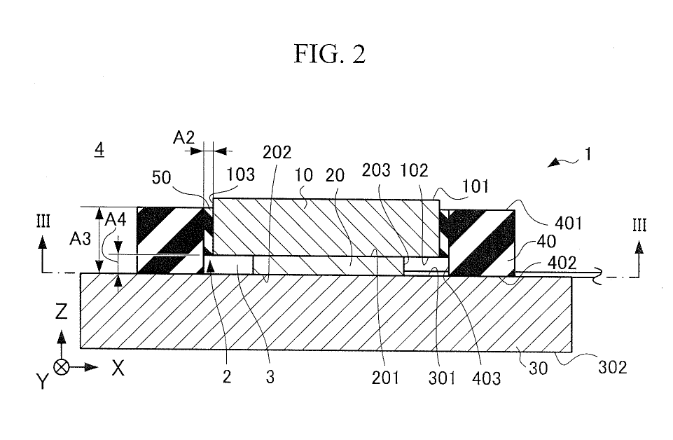

FIG. 2 is a cross-sectional view that shows a cross-section of the thermoelectric device 1 taken along a line II-II shown in FIG. 1. The heat absorber 10 includes the upper surface 101, the lower surface 102 (the first surface) that is a surface of a side opposite to the upper surface 101, and four side surfaces 103 perpendicular to the upper surface 101 and the lower surface 102. The heat absorber 10 is placed so that a perpendicular wire of the upper surface 101 goes along the Z direction. The lower surface 102 is bonded to the entire upper surface 201 of the thermoelectric module 20 using an adhesive (not shown). In other words, the lower surface 102 of the heat absorber 10 is bonded to the upper surface 201 so that the outer circumference of the upper surface 201 of the thermoelectric module 20 is located inside the outer circumference of the lower surface 102. The heat absorber 10 exchanges heat with an object coming into contact with the upper surface 101, and exchanges heat with the thermoelectric module 20 through the lower surface 102. The side surface 103 faces the filling region 2 mentioned above and comes into contact with the sealing member 50.

The thermoelectric module 20 has the upper surface 201, the lower surface 202 which is a surface of a side opposite to the upper surface 201, and four side surfaces 203 perpendicular to the surfaces 201 and 202. The thermoelectric module 20 is placed so that normal wires of the surfaces 201 and 202 go along the Z direction. Furthermore, in the thermoelectric module 20, the size in the Z axis direction is smaller than the sizes in the X axis direction and the Y axis direction. In other words, the thermoelectric module 20 is a substantially rectangular parallelepiped shape in which the areas of the surfaces 201 and 202 are greater than the area of the side portion 203. The entire lower surface 202 is bonded to the upper surface 301 of the radiator 30 using an adhesive (not shown).

In other words, the upper surface 301 of the radiator 30 is bonded to the lower surface 202 so that the outer circumference of the lower surface 202 of the thermoelectric module 20 is located inside the outer circumference of the upper surface 301. The thermoelectric module 20 moves heat from the upper surface 201 to the lower surface 202 by causing the electric current to flow through the internal electrode. The thermoelectric module 20 has a size of A4 in the Z axis direction.

The radiator 30 has the upper surface 301 (the second surface) that is greater than the lower surface 102 of the heat absorber 10 and is bonded to the lower surface 202 of the thermoelectric module 20. The radiator 30 exchanges heat with the thermoelectric module 20 through the upper surface 301. Furthermore, the radiator 30 includes the lower surface 302 provided with a plurality of protrusions (fins) (not shown) at the back of the upper surface 301. The radiator 30 radiates heat exchanged with the thermoelectric module 20 through the fins. The support member 40 has a lower surface 402 fixed to the upper surface 301 of the radiator 30 by bonding, a side surface 403 placed so as to face the side surface 103 of the heat absorber 10, and an upper surface 401 facing the lower surface 402. The support member 40 surrounds the periphery of the side surface 103 of the heat absorber 10 and the side portion 203 of the thermoelectric module 20 and is placed to be separated from the side surface 103 and the side portion 203. The filling region 2 mentioned above is formed in a gap between the side surface 103 and the support member 40. The support member 40 has a size A3 in the Z axis direction. As mentioned above, the filling region 2 has a width of A2 and the length A3−A4. Herein, the length of the filling region 2 refers to a length of a direction perpendicular to the width direction of the filing region 2, and is a difference (A3−A4) in sizes in the Z axis direction between the support member 40 and the thermoelectric module 20 in the thermoelectric device 1. The sealing member 50 fills from the upper end to the lower end of the filling region 2 in the longitudinal direction (the Z axis direction).

All the surfaces 101, 102, 201, 202, 301, 302 and 402 mentioned above are parallel to the X-Y axis plane. Furthermore, the side surfaces 103 and 403 are parallel to the Z axis.

With such a configuration, the thermoelectric device 1 moves the heat, which was absorbed by the thermoelectric module 20 from an object coming into contact with the upper surface 101 of the heat absorber 10, to the radiator 30, and radiates heat from the radiator 30. The thermoelectric module 20 is placed in a space (hereinafter, referred to as an “internal space 3”) that is formed by the heat absorber 10, the radiator 30, the support member 40 and the sealing member 50. The internal space 3 is isolated from an external space (hereinafter, referred to as an “external space 4”). For this reason, it is difficult for moisture to enter the internal space 3 from the external space 4. With such a structure, condensation of moisture on the thermoelectric module 20 is prevented, and short circuiting, rusting, and degradation of the thermoelectric module 20 itself are prevented.

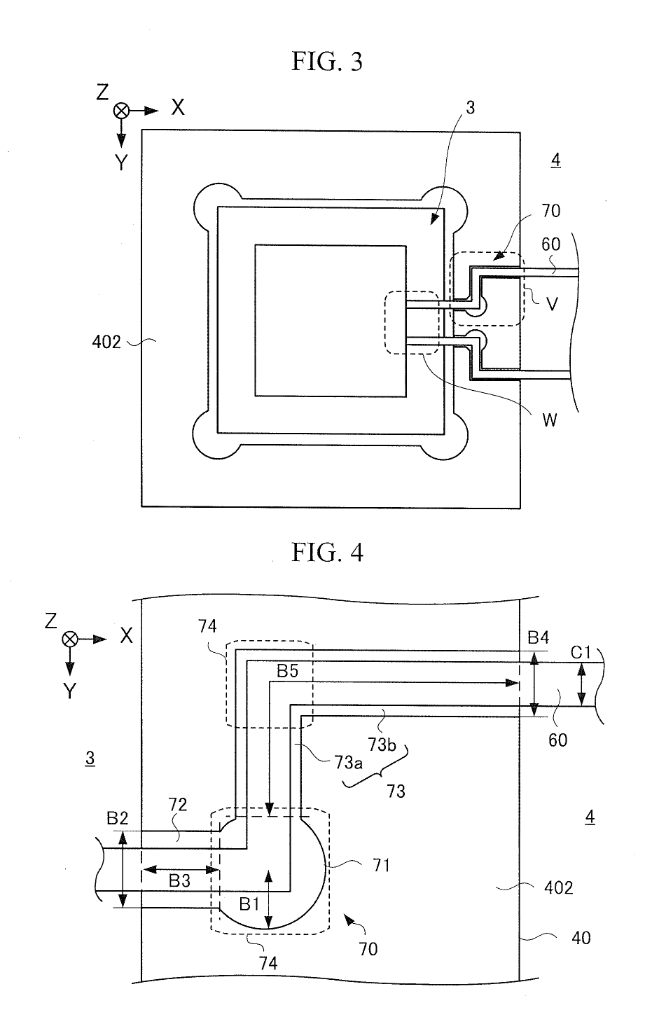

FIG. 3 is a cross-sectional view of the thermoelectric device 1 taken along a line III-III shown in FIG. 2. On the lower surface 402 of the support member 40, two bent grooves 70 are provided which connect the thermoelectric module 20 (the internal space 3) with the external space 4. Each of lead wires 60 connected to the thermoelectric module 20 is fitted into the grooves 70. The lead wire 60 is placed from the thermoelectric module 20 to the external space 4 through the grooves 70 that is formed between the upper surface 301 of the radiator 30 and the lower surface 402 of the support member. The grooves 70 are filled with the same sealing member as the sealing member 50 after the lead wire 60 is fitted to the grooves 70, thereby isolating the internal space 3 and the external space 4.

FIG. 4 shows an enlarged view of the groove 70 (a V portion of FIG. 3). The groove 70 has accumulation portion 71, and inside portion 72 and an outside portion 73. The accumulation portion 71 is formed on the lower surface 402 of the support member 40 to have a shape of a semispherical depression having a radius 131. Before the support member 40 is fixed to the surface 301 by bonding, the sealing member is injected into the accumulation portion 71, and the accumulation portion 71 accumulates the injected sealing member. The inside portion 72 is a portion in which the support member 40 is depressed along the X axis direction from the accumulation portion 71 to the internal space 3. That is, the inside portion 72 is located closer to the thermoelectric module 20 than the accumulation portion 71 in the groove 70. The inside portion 72 has a width of B2 and a length (a length from a boundary between the inside portion 72 and the accumulation portion 71 to the internal space 3) of B3. Furthermore, the inside portion 72 has a cross-section of a semicircular shape (a semicircle having a diameter of B2). The outside portion 73 is a portion in which the support member 40 is depressed from the accumulation portion 71 to the external space 4. That is, the outside portion 73 is located closer to the external space 4 than the accumulation portion 71 in the groove 70. The outside portion 73 has a width of B4 and a length (a length from a boundary between the outside portion 73 to the accumulation portion 71 to the external space 4) of B5. Furthermore, the outside portion 73 has a cross-section of a semicircular shape (a semicircle having a diameter of B4). Furthermore, the outside portion 73 has a first outside portion 73a depressed along the Y axis direction and a second outside portion 73b depressed along the X axis direction. In the groove 70, the widths B2 and B4 are narrower than a diameter (B1×2) of the accumulation portion 71 and the width B4 is narrower than the width B2. Furthermore, the length B3 is shorter than the length B5.

When fixing the support member 40 to the upper surface 301 of the radiator 30 by bonding, the lead wire 60 is fitted to the groove 70 in advance. Next, the accumulation portion 71 is stuffed with the sealing member by an amount larger than the volume of the accumulation portion 71, an adhesive (not shown) is applied to the lower surface 402 of the support member 40, and then the lower surface 402 is pushed to the upper surface 301 to bond the surfaces to each other. At this time, since the sealing member injected into the accumulation portion 71 is not completely fitted to the accumulation portion 71, the sealing member protrudes toward the inside portion 72 and the outside portion 73. The sealing member greatly protrudes toward the inside portion 72 having a width that is wider than the outside portion 73. In addition, since the length of the inside portion 72 is shorter than the outside portion 73, the sealing member protruding from the accumulation portion 71 firstly reaches the internal space 3 before reaching the outside of the groove 70.

The second outside portion 73b and the accumulation portion 71 have a portion in which a pathway connecting the internal space 3 and the external space 4 is bent. The portion (the portion becoming the corner), in which the pathway is bent, is called a bent portion 74. Since the lead wire 60 fitted to the groove 70 receives the resistance due to friction in the bent portion 74 even when the pulling or pushing force in the X axis direction is applied, it is hard for the lead wire 60 to be moved in a direction in which the force is added, compared to a configuration in which the bent portion 74 is not provided. For that reason, in the thermoelectric device 1, the length of the lead wire 60 protruding to the internal space 3 is easily secured as the length necessary to connect to the thermoelectric module 20, and when fixing the support member 40 to the radiator 30 by bonding, the positioning is easy. Furthermore, in the thermoelectric device 1, even after the respective members are attached, when force is applied to the lead wire 60, a situation is unlikely to occur where the moved lead wire 60 pulls the thermoelectric module 20 and shifts the position thereof.

As mentioned above, in the thermoelectric device 1, it is easy to constantly maintain the width of the filling region 2 in any position around the heat absorber 10, and thus it is possible to prevent the width of the tilling region 2 in a partial position from increasing, and prevent ingress of moisture.

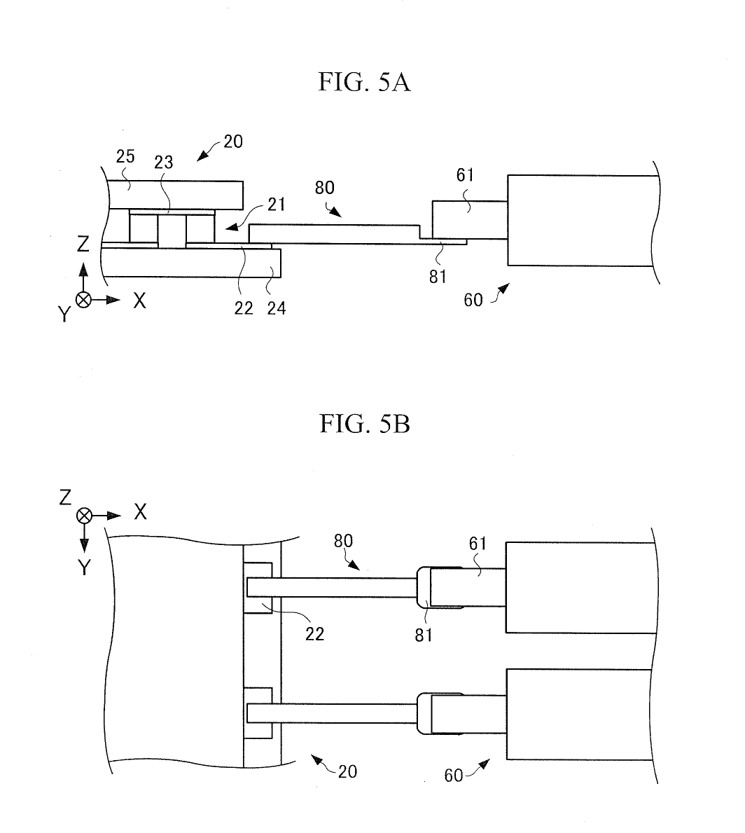

FIGS. 5A and 5B are a side view and a plan view that shows a portion (a W portion of FIG. 3) in which the lead wire 60 is connected to the thermoelectric module 20 in an enlarged manner. FIG. 5A shows the W portion when viewed in the Y axial direction, and FIG. 5B shows the W portion when viewed in the Z axis direction. The lead wire 60 has a metal wire 61 exposed at the end portion of the thermoelectric module 20. The thermoelectric module 20 has a thermoelectric element portion 21, electrodes 22 and 23 and plate-like insulators 24 and 25.

The thermoelectric element portion 21 has a plurality of groups of p-type thermoelectric elements and n-type thermoelectric elements. The electrodes 22 and 23 connect the p-type thermoelectric element and the n-type thermoelectric element so as to be electrically connected in series. Specifically, the electrode 22 connects the p-type thermoelectric elements and the n-type thermoelectric elements of the same group at a positive direction side of the Z axis, and the electrode 23 connects the p-type thermoelectric elements and the n-type thermoelectric elements of the adjacent groups at a negative direction side of the Z axis. The insulator 24 is placed so as to be connected to the electrode 22 at the negative direction side of the Z axis, and the insulator 25 is placed so as to come into contact with the electrode 23 at the positive direction side of the Z axis.

In the present embodiment, since the thermoelectric element portion 21 has a size in the Z axis direction that is smaller than the metal wire 61, when the thermoelectric element portion 21 is directly joined to the electrode 22, the metal wire 61 comes into contact with the insulator 25, and heat may be transferred between them. For this reason, in the thermoelectric device 1, they are electrically connected via a relay wire 80 that relays the electrode 22 and the metal wire 61. The relay wire 80 has a flat-plate-like flat plate portion 81 in one end thereof. The relay wire 80 is configured so that an end of the flat plate portion 81 is joined to the metal wire 61 and the other end thereof is joined to the electrode 22. In this manner, in the present embodiment, it is possible to eliminate the possibility that the electrodes 22 and 23 are short-circuited by passing through the relay wire 80. Furthermore, since a portion joining the metal wire 61 is a flat portion of the flat plate portion 81, when soldering them, the metal wire 61 is stabilized, and the work is easier than a case where the relay wire 80 does not have the flat plate portion 81. Furthermore, since the relay wire 80 and the metal wire 61 are directly bonded to each other, there is no need to provide a substrate and a connector between the relay wire 80 and the metal wire 61.

In the thermoelectric device 1, since the heat absorber 10 and the radiator 30 are connected to each other via the sealing member 50 and the support member 40, compared to a configuration in which the gap between the heat absorber 10 and the radiator 30 is filled only by the sealing member 50, the distance from the radiator 30 to the heat absorber 10 is lengthened, and it is difficult to transfer the heat.

Furthermore, in the thermoelectric device 1, the sealing member 50 has high moisture permeability compared to the heat absorber 10 and the radiator 30 formed of a metal and the support member formed of a plastic or ceramic. For that reason, the moisture most easily enters the internal space 3 from the pathway passing through the sealing member 50, that is, the pathway passing through the filling region 2. Conversely, in the thermoelectric device 1, as much as the width of the filling region 2 is narrowed, it is hard to cause the moisture to enter the internal space 3.

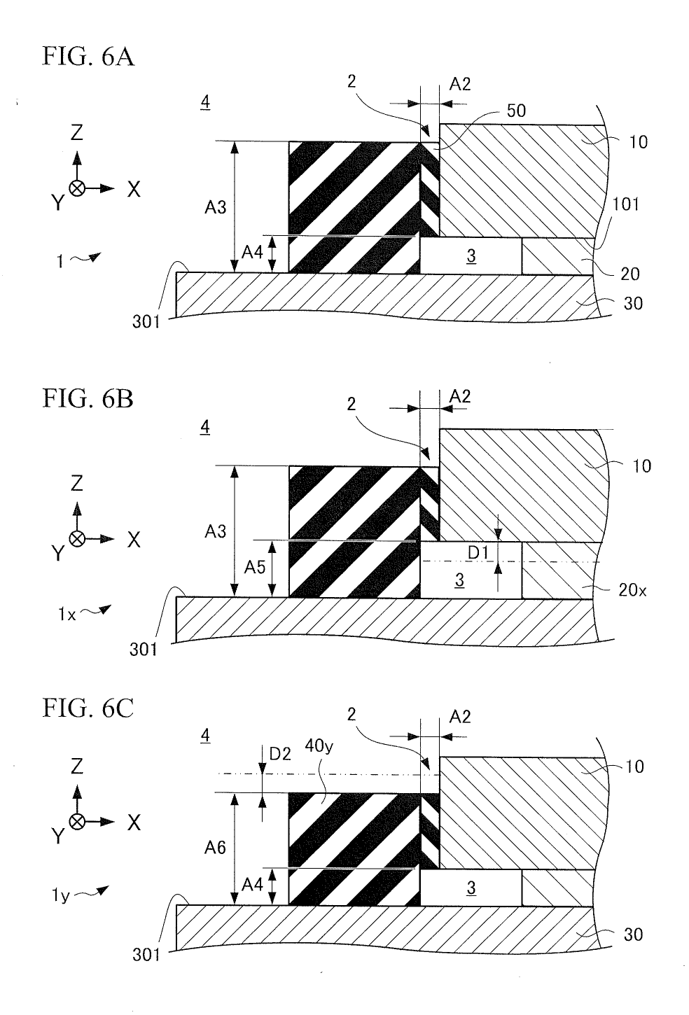

FIGS. 6A, 6B and 6C are diagrams for describing the width of the filling region 2. In FIG. 6A, one side of the filling region 2 shown in FIG. 2 is shown in an enlarged manner. In the filling region 2, a width thereof, that is, a length in the X axis direction is A2 as shown in FIGS. 1 and 2. The support member 40 has a size in the Z axis direction of A3, and the thermoelectric module 20 has a size in the Z axis direction of A4. The filling region 2 has the length in the Z axis direction of A3−A4. On the contrary, FIG. 6B shows a thermoelectric device 1x which includes a thermoelectric module 20x having a size in the Z axis direction of A5 instead of the thermoelectric module 20 of FIG. 6A. The size A5 is greater than the size A4 of FIG. 6A by the length D1. In this case, the height of the heat absorber 10 from the surface 301 of the radiator 30 is increased by D1, and the length of the filling region 2 in the Z axis direction is shortened by D1. Even if the sizes of the thermoelectric module 20 in the Z axis direction are different, since the arrangement of the heat absorber 10 and the support member 40 in the X axis direction is not changed, the length of the filling region 2 in the X axis direction is maintained in A2 and is not changed.

Furthermore, FIG. 6C shows a thermoelectric device 1y which has a support member 40 having a size in the Z axis direction of A6, instead of the support member 40 of FIG. 6A. The size A6 is smaller than the size A3 of FIG. 6A by the length D2. Even in this case, as shown in FIG. 6B, the length of the filling region 2 in the X axis direction is maintained in A2 and is not changed. In this manner, in the thermoelectric device 1, even if the sizes of the thermoelectric module 20 are different, the width (the length in the X axis direction) of the filling region 2 is not changed. Furthermore, in the thermoelectric device 1, even when the sizes of the support member 40 are different, if the difference relates to the Z axis direction, the width of the filling region 2 is not changed. The width of the filling region 2 is a width of a course (an entrance course) when moisture enters from the external space 4 to the internal space 3. According to the present embodiment, if the sizes of a direction (that is the Z axis direction) interposed by the heat absorber 10 and the radiator 30 among the sizes of the thermoelectric module 20 are different, it is possible to prevent the width of the entrance pathway of moisture blocked by the sealing member 50 from fluctuating.

The embodiment mentioned above is merely an example of the present invention. Various applications and modifications, as described below, are possible and can also be combined with each other as necessary.

### Modified Example 1

Although the flat plate portion 81 is provided in the relay wire 80 in the embodiment mentioned above, the present invention is not limited thereto. For example, the flat plate portion 81 may be provided in the metal wire 61 of the lead wire 60.

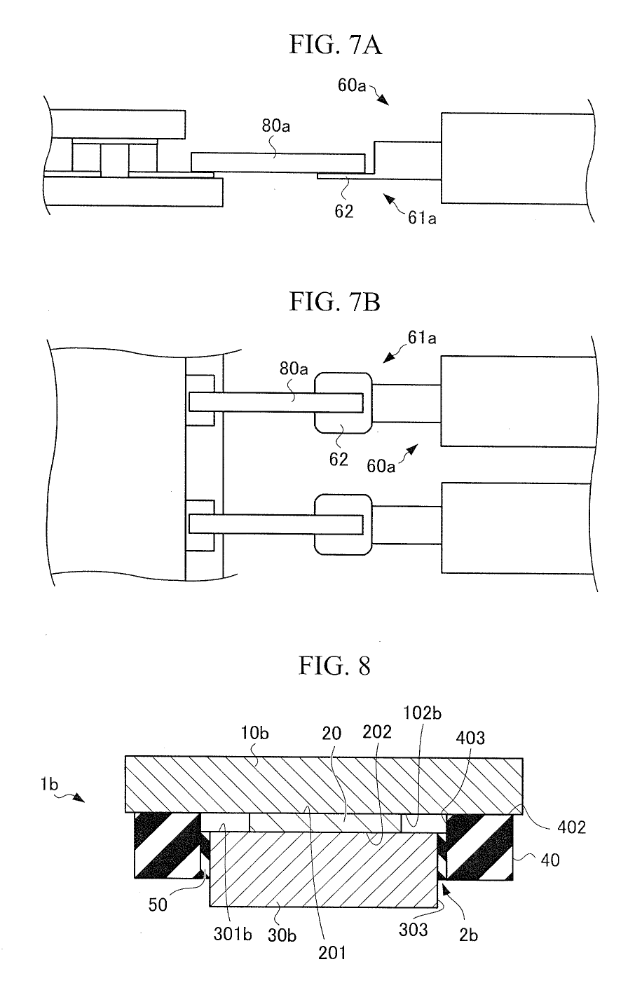

FIGS. 7A and 7B are a side view and a plan view that show a lead wire 60a according to the present modified example. The metal wire 61a of the lead wire 60a has a flat plate portion 62. The relay wire 80a does not have the flat plate portion 81 unlike the relay wire 80 according to the embodiment. Even in this case, since the portion joining the relay wire 80 and the metal wire 61 is a flat portion of the flat plate portion 62, the relay wire 80a is stabilized when soldering them, and the work is easier than a case where the metal wire 61a does not have the flat plate portion 62. Furthermore, since the relay wire 80a and the metal wire 61a are directly joined to each other, there is no need to provide a substrate or a connecter therein.

### Modified Example 2

In the heat absorber 10 and the radiator 30, although the area of the upper surface 301 (the second surface) of the radiator 30 bonded to the entirety of the lower surface 202 is greater than the area of the lower surface 102 (the first surface) of the heat absorber 10 bonded to the entirety of the upper surface 201 of the thermoelectric module 20 in the embodiment mentioned above, the relationship may be opposite.

FIG. 8 is a diagram that shows a cross section of the thermoelectric device 1b according to the present modified example. In the thermoelectric device 1b, the area of the lower surface 102b (the second surface) of the heat absorber 10b is greater than that of the upper surface 301b (the first surface) of the radiator 30b. In this case, the entirety of the lower surface 202 of the thermoelectric module 20 is bonded to the surface 301b, and the entirety of the upper surface 201 is bonded to the lower surface 102b of the heat absorber 10b. The support member 40 is configured so that the upper surface 402 provided with the grooves 70 is bonded to the lower surface 102b. A filling region 2b is formed between the side surface 403 of the support member 40 and the side surface 303 of the radiator 30b. The filling region 2b is filled with the sealing member 50.

Even in the thermoelectric device 1b, as in the embodiment mentioned above, even if the sizes of the thermoelectric module 20 are different, the width of the filling region 2b is not changed. Even if the sizes of the support member 40 are different in the Z axis direction, the width of the filling region 2b is not changed. That is, according to the present modified example, it is possible to prevent the width of the filling region 2 from being affected by a difference in size between the thermoelectric module 20 and the support member 40.

### Modified Example 3

Although the side surface 103 of the heat absorber 10 is perpendicular to the lower surface 102 bonded to the thermoelectric module 20 in the embodiment mentioned above, the present invention is not limited thereto, a non-perpendicular surface may be included, and a perpendicular surface may not be included.

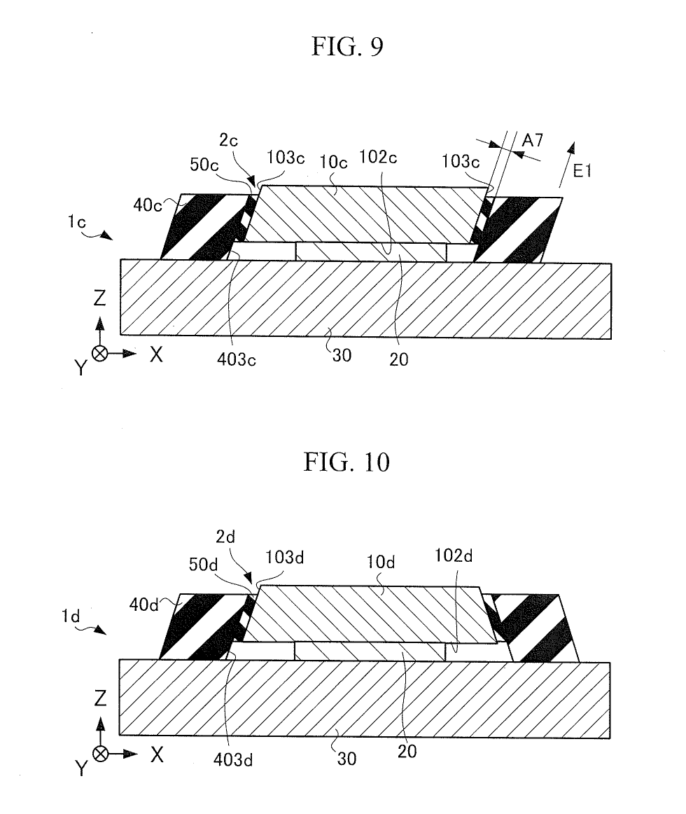

FIG. 9 is a diagram that shows a cross section of a thermoelectric device 1c according to a present modified example. The thermoelectric device 1c is different from the thermoelectric device 1 according to the embodiment in the shapes of the heat absorber 10c, the support member 40c and the sealing member 50c. In the heat absorber 10c, a lower surface 102c bonded to the thermoelectric module 20 is not perpendicular to side surfaces 103c intersecting the lower surface 102c, and these surfaces form an angle other than 90°. In the example of FIG. 9, two side surfaces 103c are parallel to each other, and the cross-section thereof is a parallelogram. The cross-section shown in FIG. 9 is one of the cross-sections in which the plane (called an XZ plane) parallel to both of the X axis direction and the Z axis direction can intersect the heat absorber 10c. In the heat absorber 10c, when a position intersecting the XZ plane is shifted in the Y axis direction, the cross-section thereof is a parallelogram even if the position is shifted in any position. In FIG. 9, an arrow E1 indicating a direction along the side surface 103c is shown. Furthermore, the support member 40c is formed so that the side surface 403c is parallel to the side surface 103c. That is, the side surface 403c is also along the direction indicated by the arrow E1. A width of the filling region 2c interposed between the side surface 103c and the side surface 403c, that is, a distance between the side surface 103c and the side surface 403c is A7. Furthermore, the sealing member 50c fills the filling region 2c.

In the thermoelectric device 1c configured as above, even if the sizes of the thermoelectric module 20 in the Z axis direction are different, by shifting the heat absorber 10c in the direction of the arrow E1, it is possible to place the heat absorber 10c and the support member 40c while maintaining the width of the filling region 2c in A7 without being changed. That is, as in the heat absorber 10c, for example, the heat absorber may be one in which the cross-section generated by intersecting the XZ plane (the YZ plane may be used) has the same shape. In addition, the heat absorber 10c has a side surface (side surfaces of a front side and a back side in the Y axis direction in FIG. 9) that is parallel to the XZ plane, and such a surface is perpendicular to the surface 102.

Furthermore, the heat absorber according to the present modified example need not include the side surface that is perpendicular to the lower surface 102. That is, when shifting the heat absorber in a certain direction, the heat absorber and the support member may be placed without changing the width of the filling region between the heat absorber and the support member. In order to do that, the side surface of the heat absorber may be inclined. Hereinafter, the direction of the straight line is called a “side surface direction”. For example, the heat absorber 10c mentioned above is also a surface in which each side surface is indicated by a set of the parallel straight lines, and the direction of the arrow E1 is a side surface direction. In the heat absorber of such a shape, the shapes of the cross-section in the XY plane are the same regardless of the position in the Z axis direction. In this case, the support member may be placed so as to surround the heat absorber and the thermoelectric module 20 by forming the inside side surface, that is, the surface facing the side surface of the heat absorber so as to be parallel to the side surface of the heat absorber.

As a result, even if the sizes of the thermoelectric module 20 in the Z axis direction are different, by placing the heat absorber so as to be shifted in the side surface direction, it is possible to prevent the width of the filling region between the heat absorber and the support member from being changed. That is, even in the present modified example, as in the present embodiment mentioned above, if the sizes of the thermoelectric module in the Z axis direction are different, it is possible to prevent the width of the entrance course of moisture covered by the sealing member from fluctuating.

### Modified Example 4

In Modified Example 3 mentioned above, although the heat absorber 10c has a shape in which the side surface 103c is a set of the straight lines parallel to each other, the present invention is not limited thereto.

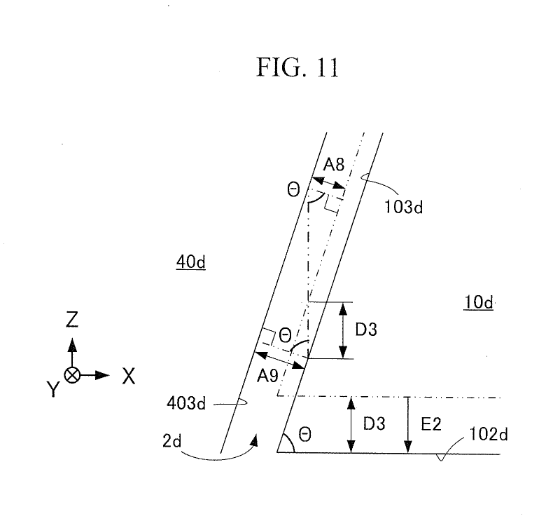

FIG. 10 is a diagram that shows a cross-section of a thermoelectric device 1d according to the present modified example. Although the thermoelectric device 1d is common to the example of FIG. 9 in that a side surface 103d of the heat absorber 10d is not perpendicular to the surface 102d which is bonded to the thermoelectric module 20 of the heat absorber 10d, the thermoelectric device 1d is different from the example of FIG. 9 in that the cross-section of the heat absorber 10d is the trapezoid. Even in this case, the support member 40d is formed so that the side surface 403d of the inside of the support member 40d is parallel to the side surface 103d of the heat absorber 10d. The filling region 2d formed between the side surface 103d and the support member 40d is filled with the sealing member 50d. In the present modified example, for example, when the size of the thermoelectric module 20 in the Z axis direction is increased, the width of the filling region 2d between the heat absorber 10d and the support member 40d becomes narrow.

FIG. 11 is a diagram for describing the width of the filling region 2d. FIG. 11 schematically shows a state where the width of the filling region 2d, that is, a distance between the side surface 103d and the side surface 403d is changed from A8 to A9, in a case where the size of the thermoelectric module 20 in the Z axis direction is reduced by the length D3.

In the present example, an angle formed between the side surface 103d and the surface 102d is θ. In the thermoelectric device 1d, since the side surface 103d is not along the same direction, in a case of shifting the heat absorber 10d in the Z axis direction, if the heat absorber 10d is also simultaneously shifted in some directions of the X axis direction and the Y axis direction, the width of the filling region of the shifted direction becomes narrow. For that reason, in the thermoelectric device 1d, the position of the heat absorber 10d is shifted only in a direction indicated by an arrow E2 along the Z axis direction. In FIG. 11, the heat absorber 10d before being shifted is indicated by a tow-dot chain line. In this case, the relationship between the distances A8 and A9 is expressed by following Formulas (1) and (2) using the angle θ and the length D3.

A9÷cos(θ)=A8÷cos(θ)+D3 (1)

A9=A8+D3×cos(θ) (2)

Formula (2) is obtained by multiplying both sides of Formula (1) by cos(θ). Since θ is an angle forming the corners of the heat absorber 10d, it is possible to take a value that is greater than 0° and is smaller than 180° (Herein, a heat absorber having the angle in the corner exceeding the 180° is not considered). In this case, cos(θ) is a value that is greater than −1 and is smaller than 1, and A9 is a value that is greater than A8−D3 and is smaller than A8+D3. In a case of θ=90° (that is, in a case where the side surface 103 is perpendicular to the surface 102 (the second surface)), A9=A8, that is, the width of the filling region is not changed, and the embodiment mentioned above corresponds thereto.

In the range mentioned above, regardless of the angle θ, the length in which the width of the filling region fluctuates, that is D3×cos(θ) becomes smaller than the distance D3 in which the heat absorber is moved in the Z axis direction. In other words, if the side surface 103 forms an angle with the surface 102, such a relationship is accomplished. If the side surface 103 has a portion which does not forms the angle with the surface 102, that is, a portion that is parallel to the surface 102, in that portion, the width of the filling region is changed by the same degree as the distance D3.

In this manner, according to the present modified example, even in a case where the thermoelectric module 20 having the different size in the Z axis direction is used, it is possible to reduce the difference in the width of the filling region less than the difference in the size of the thermoelectric module in the Z axis direction. In other words, when the sizes of the thermoelectric modules in a direction of being interposed by the heat absorber and the radiator (that is, the Z axis direction) are different, it is possible to suppress fluctuation of the width of the entrance course of moisture covered by the sealing member.

### Modified Example 5

The groove 70 may be configured so that a width of at least a part of the width in the cross-sectional direction is narrower than the thickness of the lead wire 60. The cross-sectional direction mentioned herein is a direction along the cross-section of the groove 70.

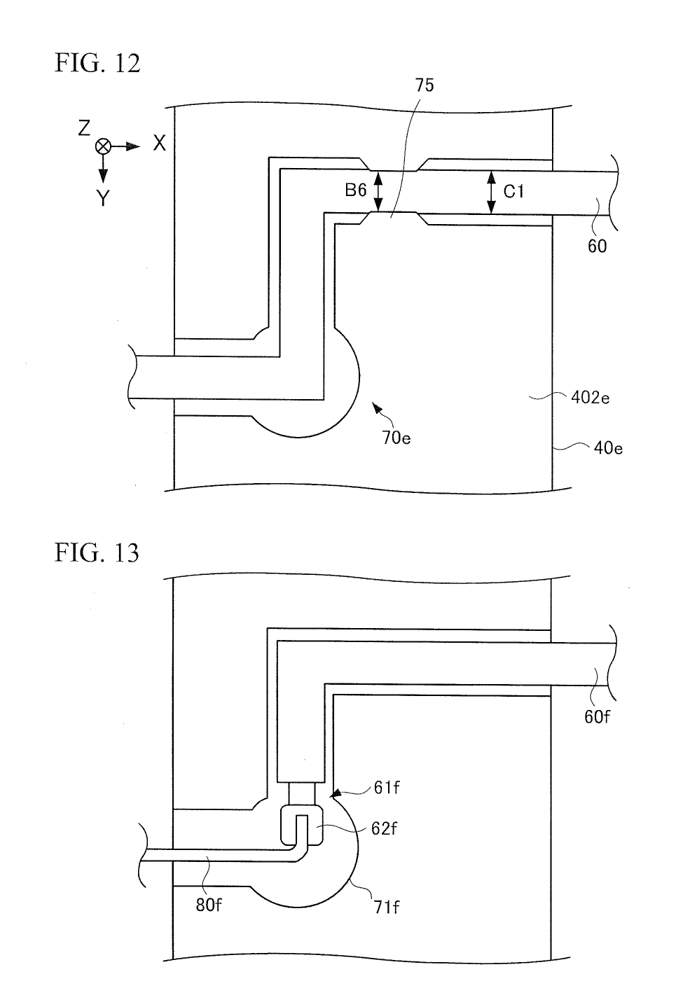

FIG. 12 is a diagram that shows a groove 70e according to the present modified example. The groove 70e is provided on a surface 402e of a support member 40e. The groove 70e has a clamping portion 75 having a width B6 that is narrower than a thickness (a diameter) C1 of the lead wire 60. The difference between the thickness C1 and the width B6 is substantially the amount of deformation which can be deformed when the coating of the lead wire 60 is compressed. For this reason, when the lead wire 60 is fitted to the clamping portion 75, the coating is compressed, and the clamping portion 75 is pushed back by force applied to the coating due to the compression, and thus, a strong frictional force acts between the lead wire 60 and the clamping portion 75, compared to the periphery.

According to the present modified example, the lead wire 60 is fixed by the frictional force, and even when the lead wire 60 is pulled in the X axis direction, it is difficult for the lead wire 60 to be shifted toward the longitudinal direction of the groove 70e. Furthermore, since the gap between the lead wire 60 and the groove 70e becomes smaller, compared to a case where the clamping portion 75 is not provided, it is difficult for the moisture to enter the internal space 3. In addition, in the clamping portion 75, even if the coating of the lead wire 60 is not deformed, the clamping portion 75 may be deformed. Furthermore, a plurality of clamping portions 75 may be provided in the groove.

### Modified Example 6

In the groove 70, the radius B1 of the accumulation portion 71 shown in FIG. 4, the width B2 and the length B3 of the inside portion 72, and the width B4 and the length B5 of the outside portion 73 may be various lengths. If the diameter B1×2 is longer than the widths B2 or B4, the radius B1 of the accumulation portion 71 may be any length. Furthermore, the widths B2 and B4 and the lengths B3 and B5 may satisfy the relationship expressed in the following Formula (3), for example, in a case where the inside portion 72 and the outside portion 73 have a semicircular cross section and the diameter of the lead wire 60 is C1.

$$( \frac{B 2}{2} \times \frac{B 2}{2} \times π \times \frac{1}{2} - \frac{C 1}{2} \times \frac{C 1}{2} \times π ) \div B 3 > ( \frac{B 4}{2} \times \frac{B 4}{2} \times π \times \frac{1}{2} - \frac{C 1}{2} \times \frac{C 1}{2} \times π ) \div B 5 \qquad ( 3 )$$

Formula (3) indicates that a value in which the cross-sectional area of the lead wire 60 is subtracted from the cross-sectional area of the inside portion 72, that is, a value, in which the cross-sectional area of the gap capable of filling the sealing member in the inside portion 72 is divided by the length, is greater than the same value in the outside portion 73. The greater the cross-sectional area is, the easier the sealing member injected into the accumulation portion 71 flows in, and the easier the groove 70 is moved. That is, satisfying Formula (3) indicates that the sealing member easily reaches the exit in the inside portion 72 compared to the outside portion 73 due to one or both of the facts that the sealing member is easily flows in, and the length to the exit (the end portion of the inside portion 72 at the thermoelectric module 20) is short.

For this reason, when the support member 40 is fixed to the radiator 30 by bonding, the sealing member injected into the accumulation portion 71 easily overflows to the inside from the inside portion 72 rather than the outside portion 73. According to the present modified example, since it is difficult for the sealing member to overflow into the external space 4 compared to the internal space 3, it is possible to prevent the appearance of the thermoelectric device from being degraded.

### Modified Example 7

Although the groove 70 is provided with one bent portion 74 in the embodiment mentioned above, two or more bent portions 74 may be provided. Alternatively, the bent portion 74 need not be provided. Moreover, preferably, the groove may be provided with many bent portions 74. The more the bent portions provided in the groove are, the greater the frictional force applied to the lead wire 60 is, and it is difficult for the lead wire 60 to be moved compared to a case where the bent portion is not provided. In addition, although the accumulation portion 71 is formed at a location corresponding to the corner of the bent portion 74 in the embodiment mentioned above, the accumulation portion may be formed at a location where the groove 70 is a straight line. In this case, the outside portion 73 may have two angles (that is, the bent port is formed only by the outside portion), and the inside portion 72 and the outside portion 73 may each have one corner (that is, the bent portion is formed by the inside portion, the accumulation portion and the outside portion).

### Modified Example 8

In the heat absorber 10, the thermoelectric module 20, and the radiator 30, although the shapes of the surfaces 101, 102, 201, 202, 301, 302 and 402 are square in the embodiments mentioned above, a rectangle, a parallelogram or the like may be used. A polygonal shape such as a triangular shape or a pentagonal shape other than the quadrangle shape or a shape including a curved line such as a circular shape or an oval shape may be used, without being limited thereto. That is, the entire surfaces (201 and 202 in the embodiment) of the thermoelectric module 20 may be bonded to the surface (102 in the embodiment) of the heat absorber 10 and the surface (301 in the embodiment) of the radiator 30. As a result, the thermoelectric module 20 can exchange heat by the entirety of the surfaces bonded to the heat absorber 10 and the radiator 30.

### Modified Example 9

In the embodiments mentioned above, although the size of the support member 40 in the Z axis direction is smaller than the length (herein, referred to as a total length) in which the size of the heat absorber 10 in the Z axis direction is added to the size of the thermoelectric module 20 in the Z axis direction, the size of the support member 40 in the Z axis direction may be the same as the total length and may be greater than the total length without being limited thereto. The size of the support member 40 in the Z axis direction may be greater than at least the size of the thermoelectric module 20 in the Z axis direction, preferably, is less than the total length, and may be close to the total length. As much as the size is close to the total length, the length (the size of the sealing member 50 in the Z axis direction in FIG. 2) of the sealing member 50 filled in the filling region 2 can be increased, and thus it is possible to prevent the moisture from entering the internal space 3 from the external space 4. Furthermore, when the thermoelectric device includes the thermoelectric module having the different sizes in the Z axis direction, as much as the length of the sealing member 50 is long, the difference in sizes in the size of the thermoelectric module and the length of the sealing member 50 is relatively reduced. For this reason, even if the sizes of the thermoelectric module are different, the length of the sealing member 50 is not changed as much. That is, a degree, in which the sealing member prevents the moisture from entering, can reduce the influence received by the fluctuation of the size of the thermoelectric module 20 in the Z axis direction.

### Modified Example 10

Although the heat absorber 10 and the radiator 30 each performs the heat absorption and the radiation in the embodiment mentioned above, such a role may be opposite. In other word, the electric current of the direction opposite to the embodiment may be caused to flow in the thermoelectric module 20, and heat may be moved in a positive direction of the Z axis. In this case, heat is absorbed from the object with which the radiator 30 comes into contact, and the heat absorber 10 radiates heat moved from the thermoelectric module 20.

### Modified Example 11

Although the thermoelectric module 20 is bonded to the entire upper surface 201 and the lower surface 202 with the lower surface 102 of the heat absorber 10 and the upper surface 301 of the radiator 30 using an adhesive in the embodiment mentioned above, the present invention is not limited thereto. For example, the thermoelectric module 20 may bond the surfaces (the surfaces 201 and 202) to the lower surface 102 and the upper surface 301 using grease, and a part of the surfaces but not the whole may be bonded. In short, the upper surface 201 may be bonded so that the outer circumference of the upper surface 201 becomes the inside of the outer circumference of the lower surface 102 of the heat absorber 10, and the lower surface 202 may be bonded so that the outer circumference of the lower surface 202 becomes the inside of the outer circumference of the upper surface 301 of the radiator 30. A bonding tape or solder may be used instead of the adhesive or the grease. Although the fixing may be performed by the bonding, the surfaces may be attached so that the surfaces are not moved by a weak bonding force. If the surfaces are bonded by inherent weight of the heat absorber 10 or the sealing material 50, the adhesive need not be used. That is, the surfaces come into close contact with each other.

### Modified Example 12

Although the lead wire 60 is placed from the thermoelectric module 20 to the external space 4 through the groove 70 in the embodiment mentioned above, the present invention is not limited thereto. For example, a hole penetrating up to the external space 4 may be opened to the side surface 403 of the support member 40, and the lead wire 60 may be placed through the hole. Furthermore, in the thermoelectric device 1, a hole may be opened to the heat absorber 10 or the radiator 30 and pass through the lead wire 60. In any case, for example, the sealing member may be filled between the hole and the lead wire 60, and it may be difficult for the moisture to enter the internal space 3 from the external space 4.

### Modified Example 13

Although the support member 40 surrounds the periphery of the side surface 103 of the heat absorber 10 and is placed at an interval with the side surface 103 in the embodiment mentioned above, a case is also included where there is a portion with no gap (that is, a contact portion) is present between the support member 40 and the side surface 103. For example, even when the heat absorber 10 is expanded due to heat or is formed to be greater than a normal case due to a manufacturing error, and as a result, a part of the side surface 103 comes into contact with the support member 40, the arrangement of the heat absorber 10 and the support member 40 in the X axis direction is not changed. Furthermore, in the thermoelectric device 1, even if the sizes of the thermoelectric module 20 in the Z axis direction are different, the arrangement of the heat absorber 10 and the support member 40 in the X axis direction is not changed. Even in the present modified example, when the sizes of the direction (that is, the Z axis direction) interposed by the heat absorber 10 and the radiator 30 among the sizes of the thermoelectric module 20 are different, it is possible to prevent the width of the entrance course of the moisture blocked by the sealing member 50 from fluctuating.

### Modified Example 14

The accumulation portion 71 can be a space capable of accumulating much sealing materials by extending in the positive direction of the Z axis. Furthermore, although the shape of the accumulation portion 71 is the semispherical shape in the embodiment mentioned above, the shape may be a cylindrical shape, a cubic shape, or a rectangular parallelepiped shape.

### Modified Example 15

Although the shapes of the cross-sections of the inside portion 72 and the outside portion 73 are a semicircular shape in the embodiment mentioned above, the shapes may be a square shape and a rectangular shape without being limited thereto. In short, the shape of the cross-section may be configured so that the lead wire 60 is placed from the internal space 3 to the external space 4 through the inside portion 72 and the outside portion 73 when the support member 40 is fixed to the surface 301 of the radiator 30 by bonding.

### Modified Example 16

Although the portion, in which the lead wire 60 is connected to the thermoelectric module 20, is placed on the internal space 3 as each shown in FIGS. 5 and 7 in the embodiment and Modified Example 1 mentioned above, the portion may be placed in the accumulation portion 71, as shown in FIG. 13. FIG. 13 shows a state where a flat plate portion 62f provided in a metal wire 61f exposed by an end portion of a lead wire 60f is connected to a relay wire 80f in the accumulation portion 71f.

### Modified Example 17

In the thermoelectric device, for example, although the width of the tilling region (the filling region 2 shown in FIG. 1) formed between the support member and the heat absorber is constantly A2 in the embodiment mentioned above, the width may be changed in the Z axis direction.

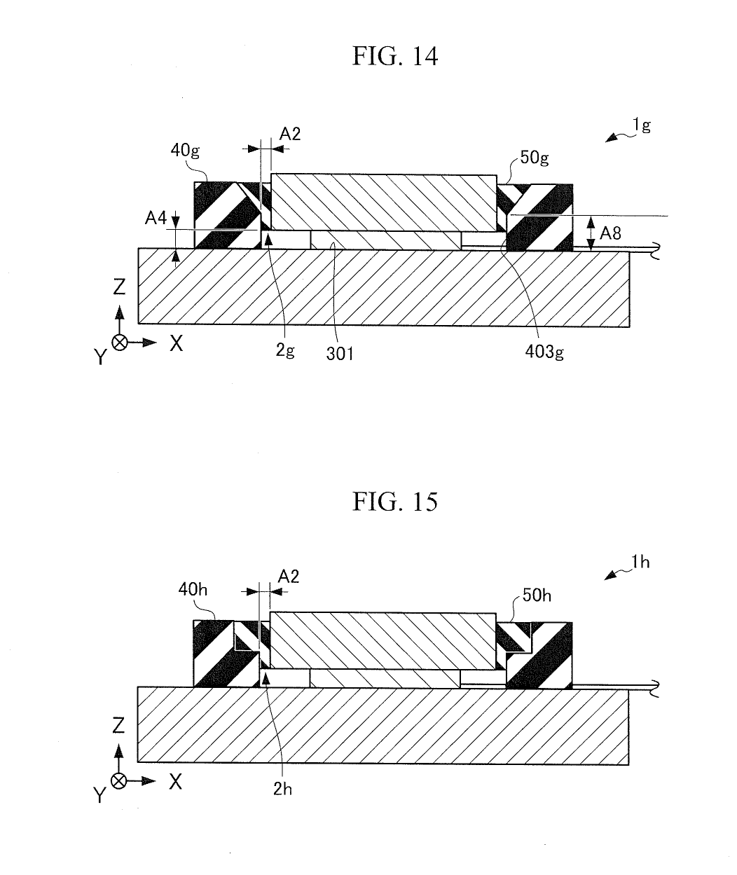

FIG. 14 is a diagram that shows a thermoelectric device 1g which is an example of a thermoelectric device according to the present modified example. The thermoelectric device 1g includes a support member 40g and a sealing member 50g. The support member 40g has a form in which the corners of the Z axis positive direction side and the X axis positive direction side of the support member 40 shown in FIG. 1 are obliquely cut. Hereinafter, a space, in which the portions of the cut corners are present, is called a “cut space”. A side surface 403g of the heat absorber 10 side of the support member 40a has a form which is cut at a position where the height from the surface 301 in the Z axis positive direction of the radiator 30 is A8, and the height A8 is greater than the size A4 of the thermoelectric module 20 in the Z axis direction. As a result, the width of the filling region 2g formed by the radiator 30 and the support member 40g in the Z axis negative direction is A2 as in the filling region 2 shown in FIG. 1. The width of the filling region 2g gradually increases at the Z axis positive direction side rather than the side surface 403g. The sealing member 50g is a synthetic resin filled in the filling region 2g, and has the same form as that of the filling region 2g.

### Modified Example 18

FIG. 15 is a diagram that shows a thermoelectric device 1h which is an example of a thermoelectric device according to the present modified example. The thermoelectric device 1h includes a support member 40h and a sealing member 50h. The support member 40h has a form in which the corners of the Z axis positive direction side and the X axis positive direction side of the support member 40 are cut, as in the support member 40g. The support member 40h is different from the support member 40g in that the cross-section of the portion of the cut corner is a rectangular shape. Even in the thermoelectric device 1h, the width of the Z axis negative direction side of the filling region 2h formed between the support member 40h and the heat absorber 10 is A2, and the width at the Z axis positive direction side is greater than A2 on the side surface 403h. In the thermoelectric device according to the present modified example, the cut space is present as mentioned above, whereby the assembly of the heat absorber 10 putting into the space surrounded by the support member 40g is easier than when the cut space is not present.

For example, a synthetic resin having fluidity is poured from the Z axis positive direction side of the filling region into the filling region, and the filled synthetic resin is solidified, whereby the sealing member is formed. In the filling region of the thermoelectric device according to the present modified example, the width of the Z axis positive direction side is greater than when the cut space is not present and the space, from which the synthetic resin is poured, is increased. In this manner, in the thermoelectric device according to the present modified example, the operation of filling the synthetic resin is easier than when the cut space is not present. Since the width of the filling region in the Z axis negative direction side has the same size (A2) as that of the thermoelectric device 1 according to the embodiment, the moisture is hard to enter the internal space.

### Modified Example 19

In the thermoelectric device, in the embodiment and the modified examples mentioned above, although the filling region filled with the sealing member coincides with the filling region (the filling region 2 in the case of the embodiment) formed between the support member and the heat absorber, they may not necessarily coincide with each other. For example, the filling region (or the sealing member) may protrude to the internal space 3 and the external space 4 and may be set back to the filling region 2. In any case, the sealing member may be necessarily present on the path from the external space 4 to the internal space 3 via the filling region 2. As a result, the sealing member prevents the moisture from entering the internal space 3.

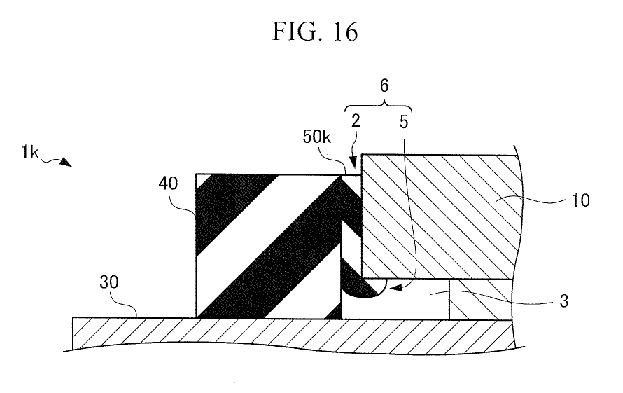

FIG. 16 is a diagram that shows a thermoelectric device lk which is an example of the thermoelectric device according to the present modified example. The thermoelectric device 1k includes a sealing member 50k that fills the filling region 6. The filling region 6 is a region constituted by the filling region 2 between the heat absorber 10 and the support member 40, and a region in which the sealing member 50k protruding to the internal space 3 fills (hereinafter, referred to as a “protrusion region 5”). In the thermoelectric device lk, the heat absorber 10, and the radiator 30 are not connected by the protrusion region 5 (or the filling region 6). That is, this means that the sealing member 50k fills a region (the filling region 6) in which the heat absorber 10 and the radiator 30 are not connected to each other via the sealing member 50k.

If the heat absorber and the radiator are connected to each other by the sealing member, heat is moved between the heat absorber and the radiator via the sealing member. For this reason, a temperature gradient between the heat absorber and the radiator is reduced compared to a case where there is no such connection, and the performance of the thermoelectric device may drop. Even in the present modified example as well as in the embodiment and the modified examples mentioned above, since the heat absorber and the radiator are not connected to each other via the sealing member, such a drop in the performance does not occur.

While preferred embodiments of the invention were described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A thermoelectric device comprising:
a thermoelectric module which has an upper surface serving as one of a heat absorption surface or a radiation surface, a lower surface serving as the other of the heat absorption surface or the radiation surface, and a side portion intersecting an outer circumference of the upper surface and an outer circumference of the lower surface;
a first thermal conductor which has a first surface and a side surface intersecting the first surface and in which the first surface comes into close contact with the upper surface of the thermoelectric module so that the outer circumference of the upper surface is located inside the outer circumference of the first surface to exchange heat with the thermoelectric module through the first surface;
a second thermal conductor which has a second surface that is larger than the first surface and in which the second surface comes into close contact with the lower surface of the thermoelectric module so that the outer circumference of the lower surface is located inside the outer circumference of the second surface to exchange heat with the thermoelectric module through the second surface;
a support member which is fixed to the second surface so as to surround the periphery of the side surface of the first thermal conductor and the side portion of the thermoelectric module at intervals with the side surface and the side portion; and
a sealing member which is filled between the side surface of the first thermal conductor and the support member,
wherein the thermoelectric module is placed in an internal space which is formed by the first thermal conductor, the second thermal conductor, the support member and the sealing member and isolated from an external space.

2. The thermoelectric device according to claim 1, wherein the sealing member is separated from the second thermal conductor.

3. The thermoelectric device according to claim 1, further comprising:
a bent groove which is formed on a surface facing the second surface of the support member and allows the external space and the internal space to communicate with each other; and
a lead wire which is provided inside the groove, and has one end electrically connected to the thermoelectric module and the other end placed in the external space.

4. The thermoelectric device according to claim 3, wherein a width of a part of a width of the groove in a cross-sectional direction is narrower than a thickness of the lead wire.

5. The thermoelectric device according to claim 3, further comprising a relay wire which has a cross-sectional area that is smaller than the thickness of the lead wire and electrically connects one end of the lead wire with the thermoelectric module.
